(19) United States
(12) Patent Application Publication
(10) Pub. No.: US 2026/0332129 A1
(43) Pub. Date: Oct. 22, 2026

(54) TRANSMITTER COMPATIBLE WITH DIFFERENT POWER VOLTAGES

(71) Applicant: SigmaStar Technology Ltd., Xiamen (CN)

(72) Inventors: De Yue LAI, Shanghai (CN); Kai SUN, Shanghai (CN); Ze Wei HE, Shanghai (CN)

(21) Appl. No.: 19/417,819

(22) Filed: Dec. 12, 2025

(30) Foreign Application Priority Data
Apr. 21, 2025 (CN) 202510497663.7

(51) Int. Cl. H03H 11/28; H02H 3/20

(52) U.S. Cl. CPC H03H 11/28; H02H 3/20

(57) ABSTRACT

A transmitter includes: an input pair circuit, outputting multiple output signals through multiple signal pads according to multiple input signals, respectively; a first matching circuit, powered by a first power supply voltage, and turned on according to some control signals to operate as a load for the input pair circuit is a first mode; a second matching circuit, powered by a second power supply voltage, and turned on according to some other control signals to operate as a load for the input pair circuit is a second mode; and a voltage generating circuit, generating the multiple control signals and multiple bias voltages according to a level of one of the multiple signal pads, the first and second power supply voltages and multiple selection signals. The first and second matching circuits further perform overvoltage and leakage protection according to the bias voltages.

This application claims the benefit of China application Serial No. CN202510497663.7, filed on Apr. 21, 2025, the subject matter of which is incorporated herein by reference.

### BACKGROUND OF THE INVENTION

### Field of the Invention

The present application relates to a transmitter, and more particularly to a transmitter compatible with different power supply voltages.

### Description of the Related Art

In the prior art, a transmitter that transmits data (more particularly transmitting video/audio data) usually needs to coordinate with components (for example, variable resistors or switches) on an external circuit to enable the transmitter to adapt to different data transmission protocols. In the prior art above, when there is a change in the data transmission protocol to which the transmitter is applied, the components on the external circuit also need to be changed, causing operation complications for a user. Moreover, the components on the external circuit board also result in greater area consumption, leading to an increase in overall costs.

### SUMMARY OF THE INVENTION

In some embodiments, it is an object of the present application to provide a transmitter compatible with different power supply voltages to improve the issues of the prior art.

In some embodiments, a transmitter includes an input pair circuit, a first matching circuit, a second matching circuit and a voltage generating circuit. The input pair circuit generates a first output signal and a second output signal according to a first input signal and a second input signal, and outputs the first output signal through a first signal pad and outputs the second output signal through a second signal pad. The first matching circuit is powered by a first power supply voltage, and is selectively turned on according to a first control signal and a second control signal to operate as a load for the input pair circuit in a first mode and provide a first terminal resistance value to the first signal pad and the second signal pad. The second matching circuit is powered by a second power supply voltage, and is selectively turned on according to a third control signal and a fourth control signal to operate as a load for the input pair circuit in a second mode and provide a second terminal resistance value to the first signal pad and the second signal pad. The voltage generating circuit generates the first control signal, the second control signal, the third control signal, the fourth control signal, a first bias voltage and a second bias voltage according to a level of a corresponding signal pad between the first signal pad and the second signal pad, the first power supply voltage, the second power supply voltage and a plurality of selection signals. The first matching circuit further performs first overvoltage and leakage protection according to the first bias voltage in the second mode, and the second matching circuit further performs second overvoltage protection and leakage protection according to the second bias voltage in the first mode.

Features, implementations and effects of the present application are described in detail in preferred embodiments with the accompanying drawings below.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 is a schematic diagram of a transmitter according to some embodiments of the present application.

FIG. 2 is a schematic diagram of the transmitter in FIG. 1 according to some embodiments of the present application.

FIG. 3A is a schematic diagram of the voltage generator in FIG. 2 according to some embodiments of the present application.

FIG. 3B is a schematic diagram of the other voltage generator in FIG. 2 according to some embodiments of the present application.

### DETAILED DESCRIPTION OF THE INVENTION

All terms used in the literature have commonly recognized meanings. Definitions of the terms in commonly used dictionaries and examples discussed in the disclosure of the present application are merely exemplary, and are not to be construed as limitations to the scope or the meanings of the present application. Similarly, the present application is not limited to the embodiments enumerated in the description of the application.

The term “coupled” or “connected” used in the literature refers to two or multiple elements being directly and physically or electrically in contact with each other, or indirectly and physically or electrically in contact with each other, and may also refer to two or more elements operating or acting with each other. As given in the literature, the term “circuit” may be a device connected by at least one transistor and/or at least one active element by a predetermined means so as to process signals.

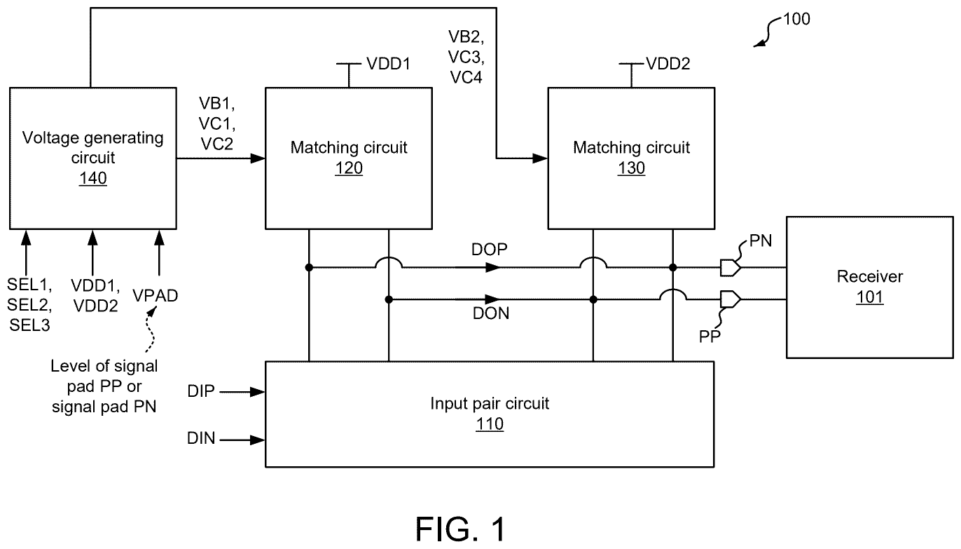

FIG. 1 shows a schematic diagram of a transmitter 100 according to some embodiments of the present application. In some embodiments, the transmitter 100 is operable in multiple modes using different power supply voltages. For example, when the transmitter 100 operates in a first mode, a power supply voltage VDD1 mainly used by the transmitter 100 is about 1.8 V. Alternatively, when the transmitter 100 operates in a second mode, a power supply voltage VDD2 mainly used by the transmitter 100 is about 3.3 V. In other words, the transmitter 100 is compatible with different power supply voltages (for example, the power supply voltage VDD1 and the power supply voltage VDD2 mentioned above, wherein the power supply voltage VDD1 is lower than the power supply voltage VDD2). In some embodiments, the first mode and the second mode correspond to different data transmission protocols. The first mode may be, for example but not limited to, a DisplayPort (DP) mode, and the second mode may be, for example but not limited to, a High Definition Multimedia Interface (HDMI) mode.

In some embodiments, the transmitter 100 includes an input pair circuit 110, a matching circuit 120, a matching circuit 130 and a voltage generating circuit 140. The input pair circuit 110 generates an output signal DOP and an output signal DON according to an input signal DIP and an input signal DIN, and outputs the output signal DON to a receiver 101 through a signal pad PP and outputs the output signal DOP to the receiver 101 through a signal pad PN.

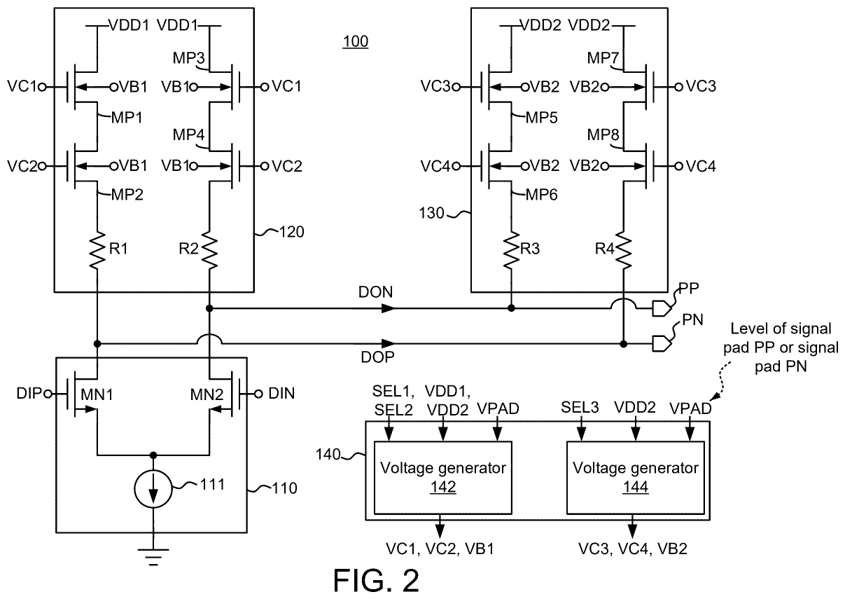

The matching circuit 120 is powered by the power supply voltage VDD1, and is selectively turned on according to a control signal VC1 and a control signal VC2 to operate as a load for the input pair circuit 110 in the first mode, and provide a terminal resistance value (for example, resistance values of the resistor R1 and the resistor R2 in FIG. 2) to the signal pad PP and the signal pad PN. Similarly, the matching circuit 130 is powered by the power supply voltage VDD2, and is selectively turned on according to a control signal VC3 and a control signal VC4 to operate as a load for the input pair circuit 110 in the second mode, and provide a terminal resistance value (for example, resistance values of the resistor R3 and the resistor R4 in FIG. 2) to the signal pad PP and the signal pad PN.

More specifically, the matching circuit 120 is turned on and the matching circuit 130 is turned off when the transmitter 100 operates in the first mode. In this case, the receiver 101 is a receiver that supports the first mode, and the matching circuit 120 may operate as a load for the input pair circuit 110 in the first mode, so as to coordinate with the input pair circuit 110 to generate the output signal DOP and the output signal DON. Meanwhile, the matching circuit 120 may provide the terminal resistance value to the receiver 101 that supports the first mode. On the other hand, the matching circuit 130 is turned on and the matching circuit 120 is turned off when the transmitter 100 operates in the second mode. In this case, the receiver 101 is a receiver that supports the second mode, and the matching circuit 130 may operate as a load for the input pair circuit 110 in the second mode, so as to coordinate with the input pair circuit 110 to generate the output signal DOP and the output signal DON. Meanwhile, the matching circuit 130 may provide the terminal resistance value to the receiver 101 that supports the second mode.

The voltage generating circuit 140 generates the multiple control signals VC1 to VC4, a bias voltage VB1 and a bias voltage VB2 according to a level of a corresponding signal pad (the signal pad PP in this example, but may be the signal pad PN in another example) between the signal pad PP and the signal pad PN, the power supply voltage VDD1, the power supply voltage VDD2 and multiple selection signals SEL1, SEL2 and SEL3. The matching circuit 120 may further perform first overvoltage and leakage current protection according to the bias voltage VB1 in the second mode, so as to ensure that a cross voltage between two terminals of an internal transistor in the matching circuit 120 does not become overly high in the second mode and prevent the internal transistor from generating undesired leakage current. Similarly, the matching circuit 130 may further perform second overvoltage and leakage protection according to the bias voltage VB2 in the first mode, so as to ensure that a cross voltage between two terminals of an internal transistor in the matching circuit 130 does not become overly high in the first mode and prevent the internal transistor from generating undesired leakage current.

FIG. 2 shows a schematic diagram of the transmitter 100 in FIG. 1 according to some embodiments of the present application. The input pair circuit 110 includes a transistor MN1, a transistor MN2 and a current source 111. A first terminal (for example, the drain) of the transistor MN1 is coupled to the signal pad PN and generates the output signal DOP, a second terminal (for example, the source) of the transistor MN1 is coupled to ground through the current source 111, and a control terminal (for example, the gate) of the transistor MN1 receives the input signal DIP. A first terminal of the transistor MN2 is coupled to the signal pad PP and generates the output signal DON, a second terminal of the transistor MN2 is coupled to ground through the current source 111, and a control terminal of the transistor MN2 receives the input signal DIN.

The matching circuit 120 includes a transistor MP1, a transistor MP2, a transistor MP3, a transistor MP4, a resistor R1 and a resistor R2. A first terminal (for example, the source) of the transistor MP1 receives the power supply voltage VDD1, a second terminal (for example, the drain) of the transistor MP1 is coupled to a first terminal of the transistor MP2, and a control terminal (for example, the gate) of the transistor MP1 receives the control signal VC1. A second terminal of the transistor MP2 is coupled to the signal pad PN through the resistor R1, and a control terminal of the transistor MP2 receives the control signal VC2. A first terminal of the transistor MP3 receives the power supply voltage VDD1, a second terminal of the transistor MP3 is coupled to a first terminal of the transistor MP4, and a control terminal of the transistor MP3 receives the control signal VC1. A second terminal of the transistor MP4 is coupled to the signal pad PP through the resistor R2, and a control terminal of the transistor MP4 receives the control signal VC2.

With the configuration above, the transistor MP1 and the transistor MP3 may receive the power supply voltage VDD1 and are selectively turned on according to the control signal VC1. The resistor R1 is coupled to the signal pad PN, and the resistor R2 is coupled to the signal pad PP, so as to provide the terminal resistance value above (which may be, for example but not limited to, 50 ohms). The transistor MP2 is coupled between the transistor MP1 and the resistor R1, and is selectively turned on according to the control signal VC2. The transistor MP4 is coupled between the transistor MP3 and the resistor R2, and is selectively turned on according to the control signal VC2. On the other hand, the base of each of the transistor MP1, the transistor MP2, the transistor MP3 and the transistor MP4 further receives the bias voltage VB1, and each of these transistors adjusts a threshold voltage thereof according to the bias voltage VB1 to implement leakage protection.

Similarly, the matching circuit 130 includes a transistor MP5, a transistor MP6, a transistor MP7, a transistor MP8, a resistor R3 and a resistor R4. A first terminal of the transistor MP5 receives the power supply voltage VDD2, a second terminal of the transistor MP5 is coupled to a first terminal of the transistor MP6, and a control terminal of the transistor MP5 receives the control signal VC3. A second terminal of the transistor MP6 is coupled to the signal pad PP through the resistor R3, and a control terminal of the transistor MP6 receives the control signal VC4. A first terminal of the transistor MP7 receives the power supply voltage VDD2, a second terminal of the transistor MP7 is coupled to a first terminal of the transistor MP8, and a control terminal of the transistor MP7 receives the control signal VC3. A second terminal of the transistor MP8 is coupled to the signal pad PN through the resistor R4, and a control terminal of the transistor MP8 receives the control signal VC4.

With the configuration above, the transistor MP5 and the transistor MP7 may receive the power supply voltage VDD2 and are selectively turned on according to the control signal VC3. The resistor R3 is coupled to the signal pad PP, and the resistor R4 is coupled to the signal pad PN, so as to provide the terminal resistance value above (which may be, for example but not limited to, 50 ohms). The transistor MP6 is coupled between the transistor MP5 and the resistor R3, and is selectively turned on according to the control signal VC4. The transistor MP8 is coupled between the transistor MP7 and the resistor R4, and is selectively turned on according to the control signal VC4. On the other hand, the base of each of the transistor MP5, the transistor MP6, the transistor MP7 and the transistor MP8 further receives the bias voltage VB2, and each of these transistors adjusts a threshold voltage thereof according to the bias voltage VB2 to implement leakage current protection.

In some embodiments, the voltage generating circuit 140 includes a voltage generator 142 and a voltage generator 144. The voltage generator 142 generates the control signal VC1, the control signal VC2 and the bias voltage VB1 provided to the matching circuit 120. The voltage generator 144 generates the control signal VC3, the control signal VC4 and the bias voltage VB2 provided to the matching circuit 130.

Possible application scenarios of the transmitter 100 are described below. In the first scenario, the transmitter 100 is applied in the first mode (to be referred to as the DP mode), and the power supply voltage VDD2 is present in the chip environment of such application. In other words, in the first scenario, both of the power supply voltage VDD1 and the power supply voltage VDD2 are energized. In this case, the power supply voltage VDD1 is about 1.8 V, the power supply voltage VDD2 is about 3.3 V, and amplitude ranges of levels on the signal pad PN and the signal pad PP are about 0 V to 1.8 V. In the application in the first mode, the control signal VC1 and the control signal VC2 are set to 0 V, and the matching circuit 120 is accordingly turned on. On the other hand, the control signal VC3 is set to 3.3 V and the control signal VC4 is set to 1.65 V (that is, one half of the power supply voltage VDD2), such that the matching circuit 130 is accordingly turned off, and meanwhile the cross voltage between two terminals of each of the transistor MP5, the transistor MP6, the transistor MP7 and the transistor MP8 is prevented from becoming overly high. Moreover, the bias voltage VB1 is set to be equal to the power supply voltage VDD1 (for example, 1.8 V), and the bias voltage VB2 is set to be equal to the power supply voltage VDD2 (for example, 3.3 V). Thus, the base of the internal transistor in the matching circuit 130 is able to receive a corresponding maximum potential, thereby preventing the matching circuit 130 that is turned off from generating leakage current.

In the second scenario, the transmitter 100 is applied in the first mode (that is, the DP mode), with however the power supply voltage VDD2 absent in the chip environment of such application. In other words, in the second scenario, the power supply voltage VDD1 is energized but the power supply voltage VDD2 is not. In this case, the power supply voltage VDD1 is about 1.8 V, the power supply voltage VDD2 is about 1.8 V, and the amplitude ranges of the levels on the signal pad PN and the signal pad PP are about 0 V to 1.8 V. In the application in the first mode, the control signal VC1 and the control signal VC2 are set to 0 V, and the matching circuit 120 is accordingly turned on. On the other hand, the control signal VC3 is set to 1.8 V and the control signal VC4 is set to 0.9 V (that is, one half of the power supply voltage VDD2), and the matching circuit 130 is accordingly turned off. Moreover, the bias voltage VB1 is set to be equal to the power supply voltage VDD1 (for example, 1.8 V), and the bias voltage VB2 is set to be equal to the power supply voltage VDD2 (1.8 V at this point). Thus, the base of the internal transistor in the matching circuit 130 is still able to receive a corresponding maximum potential.

In the third scenario, the transmitter 100 is applied in the second mode (that is, the HDMI mode). In the third scenario, both of the power supply voltage VDD1 and the power supply voltage VDD2 are energized. In this case, the power supply voltage VDD1 is about 1.8 V, the power supply voltage VDD2 is about 3.3 V, and the amplitude ranges of the levels on the signal pad PN and the signal pad PP are about 2.3 V to 3.3 V. In the application in the second mode, the control signal VC3 and the control signal VC4 are set to 1.65 V (that is, one half of the power supply voltage VDD2), and the matching circuit 130 is accordingly turned on. On the other hand, the control signal VC2 is set to 3.3 V (that is, equal to the power supply voltage VDD2), and the control signal VC1 is set to 1.65 V, such that the matching circuit 120 is accordingly turned off, and meanwhile the cross voltage between two terminals of each of the transistor MP1 and the transistor MP3 is prevented from becoming overly high. Moreover, the bias voltage VB1 is set to be equal to the level of the signal pad PP (or the signal pad PN), and the bias voltage VB2 is set to be equal to the power supply voltage VDD2. Thus, the base of the internal transistor in the matching circuit 120 is able to receive the bias voltage VB1 higher than the power supply voltage VDD1, thereby increasing the threshold voltage of the internal transistor and reducing leakage current generated by the internal transistor.

In the fourth scenario, the transmitter 100 is not energized (for example, the transmitter 100 is in an off state). In other words, in the fourth scenario, neither of the power supply voltage VDD1 nor the power supply voltage VDD2 is energized. When the transmitter 100 is not energized, the signal pad PP and the signal pad PN may contain signals coupled from the receiver 101. In this case, the levels of the signal pad PP or the signal pad PN may get as high as 3.3 V. To prevent the cross voltage between two terminals of any internal transistor in the transmitter 100 from becoming overly high, when the transmitter 100 is not energized, the voltage generating circuit 140 may set the control signal VC2, the control signal VC4, the bias voltage VB1 and the bias voltage VB2 to be equal to the level of the signal pad PP (or the signal pad PN), and set the control signal VC1 and the control signal VC3 to be equal to one half of the level of the signal pad PP (or the signal pad PN).

The voltage settings of the four scenarios may be organized as the table below, and the levels of the related signals may be set by the voltage generating circuit 140.

| | | | Level of | | |
|---|---|---|---|---|---|
| | | | signal | | |
| | | | pad (to be | | |
| | | | referred to as | | |
| Application | | | VPAD | Matching | Matching |
| scenario | VDD2 | VDD1 | below) | circuit 120 | circuit 130 |
| First | 3.3 V | 1.8 V | 0 V to | VC1: 0 V | VC3: 3.3 V |
| scenario | (Energized) | (Energized) | 1.8 V | VC2: 0 V | VC4: 1.65 V |
| (First | | | | VB1: 1.8 V | VB2: 3.3 V |
| mode) | | | | | |
| Second | 1.8 V | 1.8V | 0 V to | VC1: 0 V | VC3: 1.8 V |
| scenario | (Not | (Energized) | 1.8 V | VC2: 0 V | VC4: 0.9 V |
| (First | energized) | | | VB1: 1.8 V | VB2: 1.8 V |
| mode) | | | | | |
| Third | 3.3 V | 1.8 V | 2.3 V to | VC1: 1.65 V | VC3: 1.65 V |
| scenario | (Energized) | (Energized) | 3.3 V | VC2: 3.3 V | VC4: 1.65 |
| (Second | | | | VB1: Equal | V |
| mode) | | | | to VPAD | VB2: 3.3 V |
| Fourth | 0 V | 0 V | 3.3 V | VC1: One | VC3: One |
| scenario | (Not | (Not | | half of | half of |
| (Transmitter | energized) | energized) | | VPAD | VPAD |
| 100 is off) | | | | VC2: Equal | VC4: Equal |
| | | | | to VPAD | to VPAD |
| | | | | VB1: Equal | VB2: Equal |
| | | | | to VPAD | to VPAD |

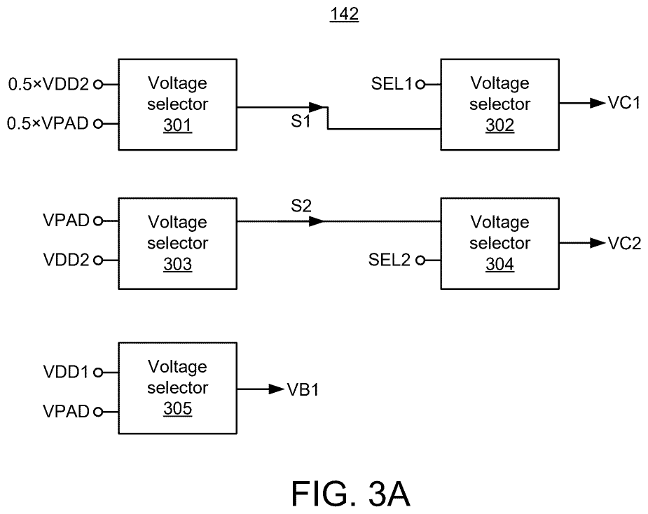

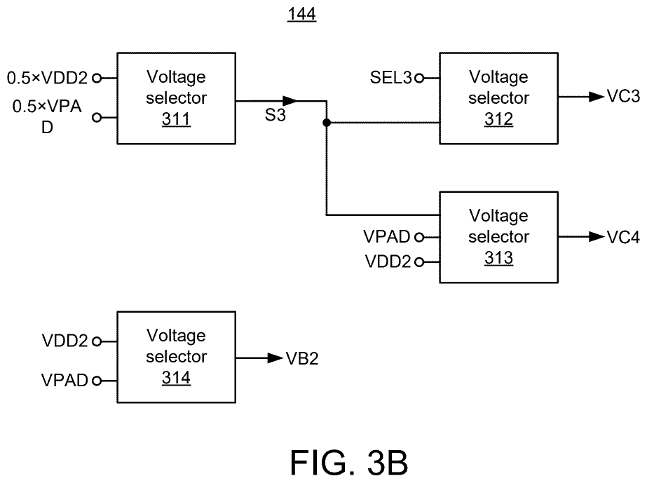

FIG. 3A shows a schematic diagram of the voltage generator 142 in FIG. 2 according to some embodiments of the present application. The voltage generator 142 includes a voltage selector 301, a voltage selector 302, a voltage selector 303, a voltage selector 304 and a voltage selector 305. The voltage selector 301 outputs one half of the power supply voltage VDD2 as a signal S1 when the power supply voltage VDD2 is energized, and outputs one half of the level of the signal pad PP (or the signal pad PN) (that is, VPAD in the table above) as the signal S1 when the power supply voltage VDD2 is not energized. The voltage selector 302 outputs a predetermined low voltage (for example but not limited to, ground level or 0 V in the table above) or the signal S1 as the control signal VC1 according to the selection signal SEL1. For example, the level of the selection signal SEL1 is set to be equal to the power supply voltage VDD1 in the first mode, and is set to the predetermined low voltage in the second mode. In the first mode, the voltage selector 302 may output the predetermined low voltage as the control signal VC1 according to the selection signal SEL1. Alternatively, in the second mode, the voltage selector 302 may output the signal S1 as the control signal VC1 according to the selection signal SEL1.

The voltage selector 303 outputs the power supply voltage VDD2 as a signal S2 when the power supply voltage VDD2 is energized, and outputs the level of the signal pad PP (or the signal pad PN) (that is, VPAD in the table above) as the signal S2 when the power supply voltage VDD2 is not energized. The voltage selector 304 may output the predetermined low voltage or the signal S2 as the control signal VC2 according to the selection signal SEL2. In some embodiments, the level of the selection signal SEL2 is set to be equal to the power supply voltage VDD1 in the first mode, and is set to the predetermined low voltage in the second mode. The voltage selector 305 outputs the power supply voltage VDD1 as the bias voltage VB1 when the power supply voltage VDD1 is energized, and outputs the level of the signal pad PP (or the signal pad PN) as the bias voltage VB1 when the power supply voltage VDD1 is not energized.

In some embodiments, each of the voltage selector 301, the voltage selector 303 and the voltage selector 305 may be implemented by a voltage comparator, which may compare two voltages received and output, between these two voltages, one having a higher level as a corresponding output. In some embodiments, the voltage comparator above may be implemented by two cross-coupled P-type transistors; however, the present application is not limited to the example above. In some embodiments, each of the voltage selector 302 and the voltage selector 304 may be implemented by a multiplexer, which may generate a corresponding output according to a corresponding selection signal. The implementation details of the multiple circuits above are merely examples, and are not to be construed as limitation to the present application.

FIG. 3B shows a schematic diagram of the voltage generator 144 in FIG. 2 according to some embodiments of the present application. The voltage generator 144 includes a voltage selector 311, a voltage selector 312, a voltage selector 313 and a voltage selector 314. The voltage selector 311 outputs one half of the power supply voltage VDD2 as a signal S3 when the power supply voltage VDD2 is energized, and outputs one half of the level of the signal pad PP (or the signal pad PN) as the signal S3 when the power supply voltage VDD2 is not energized. The voltage selector 312 may output the signal S3 or a predetermined high voltage (which may be equal to the power supply voltage VDD2) as the control signal VC3 according to the selection signal SEL3. For example, the level of the selection signal SEL3 is set to be equal to the power supply voltage VDD2 in the first mode, and is set to be equal to the predetermined low voltage above in the second mode. For example, when the level of the selection signal SEL3 is equal to the power supply voltage VDD2, the voltage selector 312 outputs the predetermined high voltage as the control signal VC3. Alternatively, when the selection signal SEL3 is set to the predetermined low voltage, the voltage selector 312 outputs the signal S3 as the control signal VC3.

The voltage selector 313 outputs the signal S3 as the control signal VC4 when the power supply voltage VDD2 is energized, and outputs the level VPAD of the signal pad PP (or the signal pad PN) as the control signal VC4 when the power supply voltage VDD2 is not energized. In other words, the voltage selector 313 may output the signal S3 or the level VPAD of the signal pad PP (or the signal pad PN) as the control signal VC4 according to the power supply voltage VDD2. The voltage selector 314 outputs the power supply voltage VDD2 as the bias voltage VB2 when the power supply voltage VDD2 is energized, and outputs the level VPAD of the signal pad PP (or the signal pad PN) as the bias voltage VB2 when the power supply voltage VDD2 is not energized.

In some embodiments, each of the voltage selector 311 and the voltage selector 314 may be implemented by the voltage comparator above. In some embodiments, each of the voltage selector 312 and the voltage selector 313 may be implemented by the multiplexer above. The implementation details of the multiple circuits above are merely examples, and are not to be construed as limitation to the present application. In some embodiments, the transmitter 100 may include multiple voltage dividing circuits (not shown), which may generate one half of the level of the power supply voltage VDD2 (which may be 0.5*VDD2 in FIG. 3A or FIG. 3B) according to the power supply voltage VDD2, and may generate one half of the level of the level VPAD (for example, 0.5*VPAD in FIG. 3A or FIG. 3B) according to the level VPAD of the signal pad PP (or the signal pad PN).

In conclusion, the transmitter provided according to some embodiments of the present application is compatible with multiple different power supply voltages and multiple modes corresponding to different data transmission protocols, and is able to provide corresponding overvoltage and leakage protection in the individual modes. Moreover, the transmitter provided according to some embodiments of the present application is able to set individual voltages by means of adjusting circuit settings in a chip to adapt to different modes, without adjusting components outside the chip. Thus, the area taken up by external components of the chip can be reduced and ease of product application can be improved.

While the present application has been described by way of example and in terms of the preferred embodiments, it is to be understood that the disclosure is not limited thereto. Various modifications may be made to the technical features of the present application by a person skilled in the art on the basis of the explicit or implicit disclosures of the present application. The scope of the appended claims of the present application therefore should be accorded with the broadest interpretation so as to encompass all such modifications.

What is claimed is:

1. A transmitter, comprising:
an input pair circuit, generating a first output signal and a second output signal according to a first input signal and a second input signal, outputting the first output signal through a first signal pad, and outputting the second output signal through a second signal pad;
a first matching circuit, powered by a first power supply voltage, and selectively turned on according to a first control signal and a second control signal to operate as a load for the input pair circuit in a first mode and provide a first terminal resistance value to the first signal pad and the second signal pad;
a second matching circuit, powered by a second power supply voltage, and selectively turned on according to a third control signal and a fourth control signal to operate as a load for the input pair circuit in a second mode and provide a second terminal resistance value to the first signal pad and the second signal pad; and
a voltage generating circuit, generating the first control signal, the second control signal, the third control signal, the fourth control signal, a first bias voltage and a second bias voltage according to a level of a corresponding signal pad between the first signal pad and the second signal pad, the first power supply voltage, the second power supply voltage and a plurality of selection signals,
wherein the first matching circuit further performs a first overvoltage and leakage protection according to the first bias voltage in the second mode, and the second matching circuit further performs a second overvoltage and leakage protection according to the second bias voltage in the first mode.

2. The transmitter according to claim 1, wherein when the transmitter is not energized, the voltage generating circuit sets a level of each of the second control signal, the fourth control signal, the first bias voltage and the second bias voltage to be equal to the level of the corresponding signal pad, and sets a level of each of the first control signal and the third control signal to be one half of the level of the corresponding signal pad.

3. The transmitter according to claim 1, wherein the first mode and the second mode correspond to different data transmission protocols, and the first power supply voltage is lower than the second power supply voltage.

4. The transmitter according to claim 1, wherein the first matching circuit comprises:
a first transistor, receiving the first power supply voltage, and selectively turned on according to the first control signal;
a first resistor, coupled to the first signal pad;
a second transistor, coupled between the first transistor and the first resistor, and selectively turned on according to the second control signal;
a third transistor, receiving the first power supply voltage, and selectively turned on according to the first control signal;
a second resistor, coupled to the second signal pad; and
a fourth transistor, coupled between the third transistor and the second resistor, and selectively turned on according to the second control signal;
wherein a base of each of the first transistor, the second transistor, the third transistor and the fourth transistor further receives the first bias voltage.

5. The transmitter according to claim 1, wherein the second matching circuit comprises:
a first transistor, receiving the second power supply voltage, and selectively turned on according to the third control signal;
a first resistor, coupled to the second signal pad;
a second transistor, coupled between the first transistor and the first resistor, and selectively turned on according to the fourth control signal;
a third transistor, receiving the second power supply voltage, and selectively turned on according to the third control signal;
a second resistor, coupled to the first signal pad; and
a fourth transistor, coupled between the third transistor and the second resistor, and selectively turned on according to the fourth control signal;
wherein a base of each of the first transistor, the second transistor, the third transistor and the fourth transistor further receives the second bias voltage.

6. The transmitter according to claim 1, wherein in the first mode, when both of the first power supply voltage and the second power supply voltage are energized, the voltage generating circuit sets levels of both of the first control signal and the second control signal to a predetermined low voltage, sets the first bias voltage to be equal to the first power supply voltage, sets levels of both of the third control signal and the second bias voltage to be equal to the second power supply voltage, and sets a level of the fourth control signal to be one half of the second power supply voltage.

7. The transmitter according to claim 1, wherein in the first mode, when the first power supply voltage is energized and the second power supply voltage is not energized, the voltage generating circuit sets levels of both of the first control signal and the second control signal to a predetermined low voltage, sets the first bias voltage to be equal to the first power supply voltage, sets levels of both of the third control signal and the second bias voltage to be equal to the first power supply voltage, and sets a level of the fourth control signal to be one half of the first power supply voltage.

8. The transmitter according to claim 1, wherein in the second mode, the voltage generating circuit sets levels of all of the first control signal, the third control signal and the fourth control signal to be one half of the second power supply voltage, sets a level of the second control signal and the second bias voltage to be equal to the second power supply voltage, and sets the first bias voltage to the level of the corresponding signal pad.

9. The transmitter according to claim 1, wherein the voltage generating circuit comprises:
a first voltage selector, outputting one half of the second power supply voltage as a first signal when the second power supply voltage is energized, and outputting one half of the level of the corresponding signal pad as the first signal when the second power supply voltage is not energized;
a second voltage selector, outputting a predetermined low voltage or the first signal as the first control signal according to a first selection signal among the plurality of selection signals, wherein a level of the first selection signal is set to be equal to the first power supply voltage in the first mode and set to the predetermined low voltage in the second mode;
a third voltage selector, outputting the second power supply voltage as a second signal when the second power supply voltage is energized, and outputting the level of the corresponding signal pad as the second signal when the second power supply voltage is not energized;
a fourth voltage selector, outputting the predetermined low voltage or the second signal as the second control signal according to a second selection signal among the plurality of selection signals, wherein a level of the second selection signal is set to be equal to the first power supply voltage in the first mode and set to the predetermined low voltage in the second mode; and
a fifth voltage selector, outputting the first power supply voltage as the first bias voltage when the first power supply voltage is energized, and outputting the level of the corresponding signal pad as the first bias voltage when the first power supply voltage is not energized.

10. The transmitter according to claim 1, wherein the voltage generating circuit comprises:
a first voltage selector, outputting one half of the second power supply voltage as a first signal when the second power supply voltage is energized, and outputting one half of the level of the corresponding signal pad as the first signal when the second power supply voltage is not energized;
a second voltage selector, outputting the first signal or a predetermined high voltage as the third control signal according to a first selection signal among the plurality of selection signals, wherein a level of the first selection signal is set to be equal to the second power supply voltage in the first mode and set to a predetermined low voltage in the second mode;
a third voltage selector, outputting the first signal as the fourth control signal when the second power supply voltage is energized, and outputting the level of the corresponding signal pad as the fourth control signal when the second power supply voltage is not energized; and
a fourth voltage selector, outputting the second power supply voltage as the second bias voltage when the second power supply voltage is energized, and outputting the level of the corresponding signal pad as the second bias voltage when the second power supply voltage is not energized.
